(19) United States
(12) Patent Application Publication
(10) Pub. No.: US 2014/0035649 A1
(43) Pub. Date: Feb. 6, 2014

(54) TUNED RESONANT CLOCK DISTRIBUTION SYSTEM

(71) Applicant: Nikola NEDOVIC, San Jose, CA (US)

(72) Inventor: Nikola NEDOVIC, San Jose, CA (US)

(73) Assignee: FUJITSU LIMITED, Kawasaki-shi (JP)

(21) Appl. No.: 13/563,507

(22) Filed: Jul. 31, 2012

(51) Int. Cl. H03K 3/01

(52) U.S. Cl. 327/299

(57) ABSTRACT

A tunable clock distribution system that includes a clock network including an inductive circuit and a capacitive circuit where at least one of the capacitive circuit or the inductive circuit is tunable. The tunable clock distribution system may further include a driving circuit and a phase determiner. The driving circuit may be configured to receive a clock signal and to distribute a resonant clock signal based on the clock signal to the clock network. The phase determiner may be configured to receive the clock signal and the resonant clock signal and to determine whether the clock signal and the resonant clock signal have a predetermined phase difference. When the clock signal and the resonant clock signal do not have the predetermined phase difference, the phase determiner may be configured to tune at least one of the capacitive circuit or the inductive circuit.

### FIELD

The embodiments discussed herein are related to a tunable resonant clock distribution system.

### BACKGROUND

Many chip-size or core-size grids and/or trees in microprocessors and integrated circuits rely on one or more clock signals to synchronize elements within the processors or circuits. As circuit size and clock frequency increase, power consumption and jitter become increasingly important to control.

Various circuits have been devised to provide high-frequency, low jitter multiphase clock distribution in microprocessors or integrated circuits.

FIG. 1 shows an example of a resonant clock distribution system 100 for one sector of an integrated circuit as is currently used in the art. In this example, a clock signal Clkᵢₙ is generated or provided from a clock generating circuit. The signal is buffered by a buffer 101 and then sent to a LC tank 110 that includes an inductor 103 having inductance Lᵣₑₛ, a parasitic capacitance C_{load} represented by capacitor 102, and parasitic system resistance Rᵣₑₛ represented by a resistor 104.

The LC tank 110 operates as charge flows back and forth through the inductor 103 and the capacitor 102 until the system resistance Rᵣₑₛ eventually depletes the charge, unless additional energy is added to the LC tank 110. In cases where the system resistance Rᵣₑₛ is low, an advantage of using the LC tank 110 is that the current is reused as it flows between the inductor 103 and the capacitor 102, thereby reducing the amount of power required to drive the resonant clock distribution system 100.

In this example, the input impedance Zᵢₙ, power dissipation P_{diss}, quality factor Q, and natural frequency ω₀ of the resonant clock distribution system 100 may be calculated from the following equations:

$${Z}_{in} = \sqrt{\frac{{L}_{res}}{{C}_{load}}} \cdot ( Q - j ) , \\ {P}_{diss} = \frac{π}{4} \cdot \frac{{C}_{load} \cdot {V}_{DD}^{2} \cdot {f}_{clk}}{Q} , \\ Q = \frac{{ω}_{o} {L}_{res}}{{R}_{res}} = \frac{1}{{R}_{res}} \cdot \sqrt{\frac{{L}_{res}}{{C}_{load}}} , and$$

$${ω}_{0} = \frac{1}{\sqrt{{L}_{res} \cdot {C}_{load}}} .$$

In this resonant clock distribution system 100, Q, or the quality factor, of the LC circuit 110 is a measure of the “goodness” or quality of the LC circuit 110. A higher value for Q corresponds to a narrower bandwidth, which is desirable in many applications. More formally, Q is the ratio of power stored to power dissipated in the reactance and resistance of the LC circuit 110. Hence, when Q is higher, driver circuits for the resonant clock distribution system 100 may be made weaker since there is less loss that must be overcome. This may be desirable since a weaker driver circuit requires less power. When Q is poor, the driver circuits may be larger to overcome the losses of the resonant clock distribution system 100. More power is dissipated, not only because more energy is required to overcome the losses of the resonant clock distribution system 100, but because the driver circuits may present larger loads to preceding clock distribution networks.

The subject matter claimed herein is not limited to embodiments that solve any disadvantages or that operate only in environments such as those described above. Rather, this background is only provided to illustrate one example technology area where some embodiments described herein may be practiced.

### SUMMARY

One aspect of the invention is a tunable clock distribution system that includes a clock network including an inductive circuit and a capacitive circuit where at least one of the capacitive circuit or the inductive circuit is tunable. The tunable clock distribution system may further include a driving circuit and a phase determiner. The driving circuit may be configured to receive a clock signal and to distribute a resonant clock signal based on the clock signal to the clock network. The phase determiner may be configured to receive the clock signal and the resonant clock signal and to determine whether the clock signal and the resonant clock signal have a predetermined phase difference. When the clock signal and the resonant clock signal do not have the predetermined phase difference, the phase determiner may be configured to tune at least one of the capacitive circuit or the inductive circuit.

The object and advantages of the embodiments will be realized and achieved at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1 is an example of a known resonant clock distribution system;

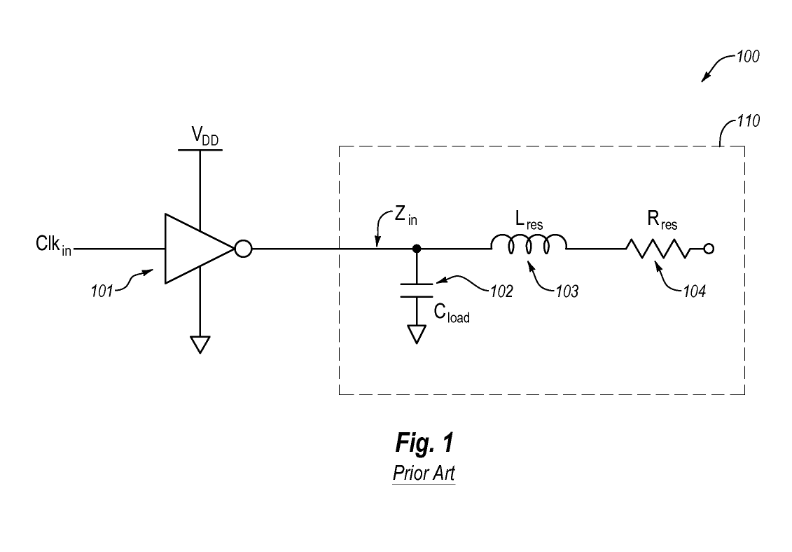

FIG. 2 is block diagram of an example tunable resonant distribution system;

FIG. 3 is an example of a tunable resonant clock distribution system;

FIG. 4 is an example of a phase detector which may be used in association with the tunable resonant distribution systems of FIG. 2 or 3;

FIG. 5A is an example of another phase detector which may be used in association with the tunable resonant distribution systems of FIG. 2 or 3;

FIG. 5B illustrates example signals which may be detected by the phase detector of FIG. 5A;

FIG. 6 is an example of another tunable resonant clock distribution system; and

FIG. 7 is a flow chart illustrating a method of tuning a resonant clock distribution system.

### DESCRIPTION OF EMBODIMENTS

Embodiments described herein relate to integrated circuits and microprocessors. More specifically, embodiments described herein relate to systems and methods for distributing a clock signal in an integrated circuit or microprocessor. Various clock distribution circuits may be used to distribute clock signals, including grids, trees, and H-tree driving circuits. In larger integrated circuits, a hierarchical architecture may be employed wherein the integrated circuit is partitioned into a plurality of sectors, with each sector being driven by an H-tree and the sector-based H-trees being driven by another H-tree distribution circuit. In other embodiments, a clock distribution circuit may include a core-size grid circuit.

In general, some microprocessor clock distribution systems may have several dozen clock-distribution sectors, which are coupled in a variety of different methods in order to provide a global clock distribution system. These clock distribution systems may be configured with phase detectors that determine a difference in phase between clocks within the clock distribution system. When unwanted differences are detected, inductance and/or capacitance of the clock distribution system may be tuned and/or adjusted to bring the clocks back into a desired phase difference to thereby reduce the power consumption of the clock distribution system.

Embodiments of the present invention will be explained with reference to the accompanying drawings.

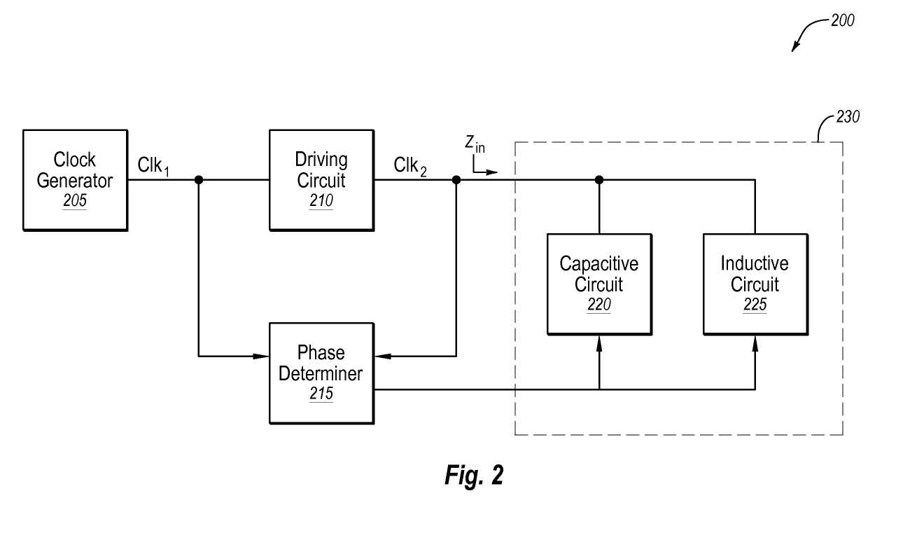

FIG. 2 is a block diagram of an example tunable resonant distribution system 200, arranged in accordance with at least some embodiments described herein. In some embodiments, the tunable resonant distribution system 200 may correspond to one sector of an integrated circuit as part of a larger clock distribution system. In other embodiments, the tunable resonant distribution system 200 may be the distribution system within an integrated circuit.

As illustrated in FIG. 2, a clock signal Clk₁ may be generated by a clock generator 205. The clock generator 205 may send the clock signal Clk1 to a driving circuit 210. The clock generator 205 may also send the clock signal Clk₁ to a phase determiner 215. The driving circuit 210 may distribute the clock signal Clk₁ to a clock network 230 as a resonant clock signal Clk₂. The clock network 230 may include a capacitive circuit 220 and an inductive circuit 225. As is described more fully below, the tunable resonant distribution system 200 may also include a phase determiner 215 that compares a phase of the clock signal Clk₁ with a phase of the resonant clock signal Clk₂.

The clock network 230 may include parasitic or inherent capacitance. This inherent capacitance may increase the power to drive the resonant clock signal Clk₂. To reduce the power to drive the resonant clock signal Clk₂, the clock network 230 may include an LC circuit or tank formed from the parasitic capacitance of the clock network 230, the capacitive circuit 220, and the inductive circuit 225.

Embodiments described herein may use the phase determiner 215 to determine the phase of the resonant clock signal Clk₂ as compared to the phase of the clock signal Clk₁ in order to determine if the clock network 230 is in resonance. For example, when the driving circuit 210 is a non-inverting circuit, the clock network 230 may be in resonance when there is a zero degree phase shift between the resonant clock signal Clk₂ and the clock signal Clk₁. As another example, when the driving circuit 210 is an inverting circuit causing the resonant clock signal Clk₂ to be an inverse of the clock signal Clk₁, the clock network 230 may be in resonance when there is a 180 degree phase shift between the resonant clock signal Clk₂ and the clock signal Clk₁. Other phase differences between the resonant clock signal Clk₂ and the clock signal Clk₁ may result in resonance of the clock network 230 as well depending on the structure of the driving circuit 210 and the clock network 230.

When the phase determiner 215 determines that the resonant clock signal Clk₂ and the clock signal Clk₁ are not in resonance, the phase determiner 215 may adjust a capacitance of the capacitive circuit 220 and/or an inductance of the inductive circuit 225 to adjust the phase of the resonant clock signal Clk₂ and bring the clock network 230 into resonance. Thus, adjusting the capacitance of the capacitive circuit 220 and/or the inductance of the inductive circuit 225 may help keep the clock network 230 in resonance. In some embodiments, the capacitance of the capacitive circuit 220 may be adjusted (tuned) using analog circuitry or digital circuitry. Alternately or additionally, the inductance of the inductive circuit 225 may be adjusted (tuned) using analog circuitry or digital circuitry.

More specifically, the embodiments described herein operate on a principle that when the clock network 230 is in resonance, an impedance Zᵢₙ of the clock network 230 is real or very close to being real. Since resistance is the real part of impedance, a device or system with a purely resistive impedance exhibits no phase shift or a predetermined phase shift between a voltage and/or a current of the system or device. Thus, when the impedance Zᵢₙ of the clock network 230 is real or very close to being real, the clock network 230 is in resonance.

Various examples of how the phase difference of the two signals Clk₁ and Clk₂ may be detected and how the capacitance and/or the inductance of the clock network 230 may be adjusted are described more fully below.

Modifications, additions, or omissions may be made to the tunable resonant distribution system 200 without departing from the scope of the present disclosure. For example, the tunable resonant distribution system 200 may include the capacitive circuit 220 and not the inductive circuit 225 or may include the inductive circuit 225 and not the capacitive circuit 220.

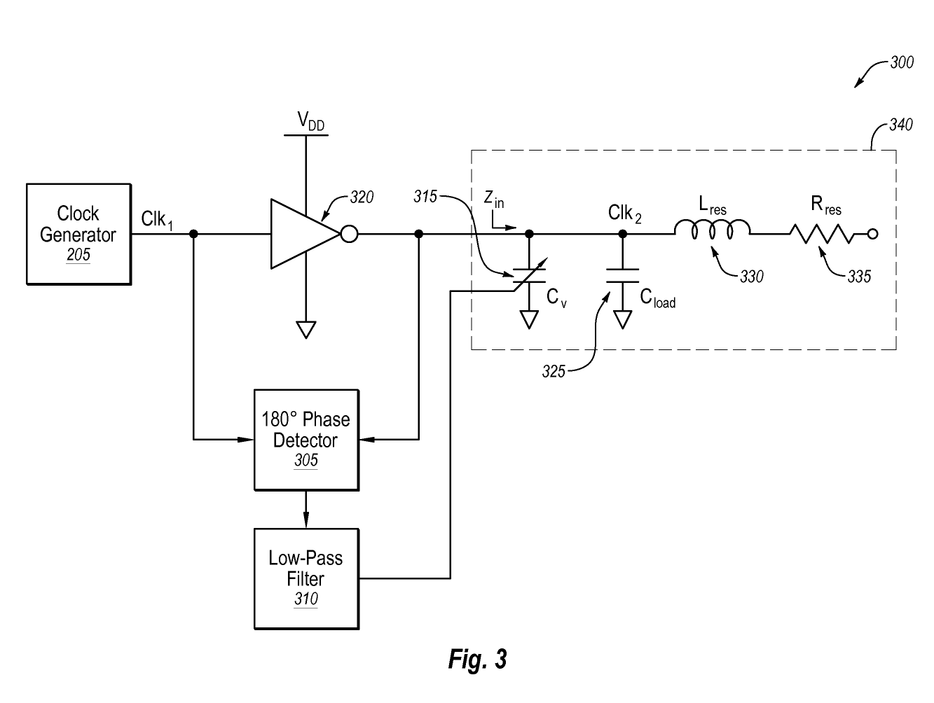

FIG. 3 is an example of a tunable resonant clock distribution system 300, arranged in accordance with at least some embodiments described herein. The tunable resonant clock distribution system 300 includes a clock generator 205 configured to generate a clock signal Clk₁. The clock signal Clk₁ is sent to an inverting amplifier 320. The inverting amplifier 320 amplifies and inverts the clock signal Clk₁ and outputs a resonant clock signal Clk₂ to a clock network 340.

The clock network 340 may include a parasitic capacitance C_{load} represented by a capacitor 325 and system resistance Rᵣₑₛ represented by a resistor 335. The clock network 340 may further include an inductor 330 having inductance Lᵣₑₛ and a variable capacitor 315 which adds a varying capacitance Cᵥ to the clock network 340. The inductor 330, the parasitic capacitance C_{load}, and the variable capacitor 315 may form an LC tank within the clock network 340.

The tunable resonant clock distribution system 300 may also include an 180° phase detector 305 and a low-pass filter 310, which together form a type of phase determiner, similar to and/or corresponding to the phase determiner 215 of FIG. 2.

The embodiment illustrated in FIG. 3 tunes the resonant clock distribution system 300 by monitoring a phase shift between the clock signal Clk₁ and the resonant clock signal Clk₂ to determine if the clock signal Clk₁ and the resonant clock signal Clk₂ are in resonance, that being 180° out of phase or very close to 180° out of phase. In particular, the 180° phase detector 305 detects a difference in phase between the clock signal Clk₁ and the resonant clock signal Clk₂. When the clock signal Clk₁ and the resonant clock signal Clk₂ are not 180° out of phase or close to 180° out of phase, the 180° phase detector 305 may send a signal to the low pass filter 310 that is passed to the variable capacitor 315. The signal may cause the variable capacitor 315 to adjust its capacitance C. By adjusting the capacitance Cᵥ of the variable capacitor 315, the 180° phase detector 305 may adjust the phase of the resonant clock signal Clk₂ and bring the clock signal Clk₁ and the resonant clock signal Clk2 into resonance.

The low pass filter 310 may be configured to filter the signal sent to the variable capacitor 315 from the 180° phase detector 305. In particular, the low pass filter 310 may filter high frequencies of the signal. As a result, differences in phase between the clock signal Clk₁ and the resonant clock signal Clk₂ due to jitter or other fast changing and/or random effects that may not reflect phase drifting between the clock signal Clk₁ and the resonant clock signal Clk₂ may not result in adjustments to the capacitance C_{V} of the variable capacitor 315.

The variable capacitor 315 may include a conventional MOSFET or other transistor where a change of voltage on the transistor changes the inherent capacitance of the transistor. As such, the variable capacitor 315 may not be an actual capacitor, but may be any element with capacitive properties.

Furthermore, the variable capacitor 315 may include a varactor, a digital capacitor, or a bank of capacitors joined by a series of switches or other means of connection. One disadvantage to using a series or bank of capacitors, however, is that increasing the number of capacitive elements or switches in the system increases the amount of power that is lost and consequently the amount of power that must be supplied by a driver to continuously switch the electrical connections. Furthermore, increasing the number of components in the system increases the inherent resistance and loss of the system.

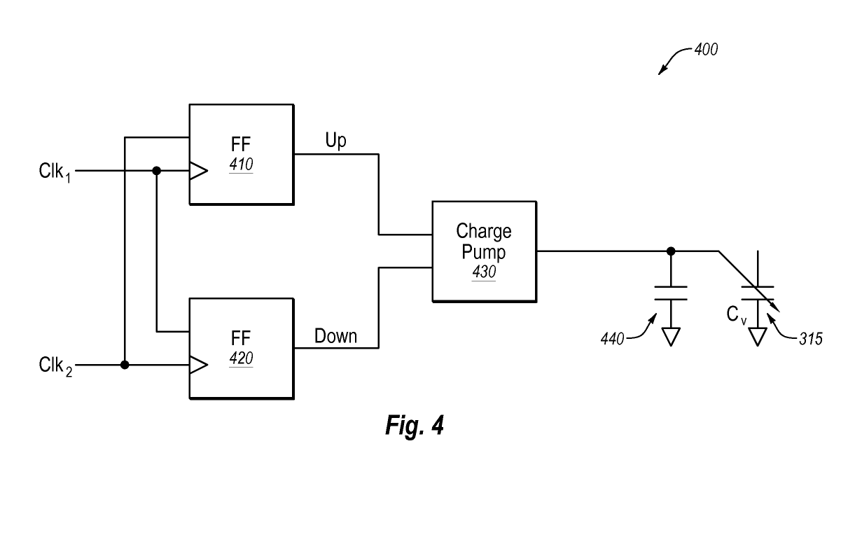

FIG. 4 is an example of a phase detector 400 that may be used in association with the tunable resonant distribution system of FIG. 2 or 3, arranged in accordance with at least some embodiments described herein. The phase detector 400 may correspond to and/or be similar to the 180° phase detector 305 of FIG. 3. The phase detector 400 may include a pair of flip-flop circuits 410 and 420 in addition to a charge pump 430 with its associated capacitor 440.

The phase detector 400 may be configured to detect a phase difference between a first clock signal Clk₁ and a second clock signal Clk₂, and when the phase difference is not equal to or approximately equal to 180°, to send a signal to vary a capacitance C_{V} of a variable capacitor 315. The variable capacitor 315 may correspond to the variable capacitor 315 of FIG. 3.

To detect the phase difference, the flip-flop circuit 410 may be configured to latch a value of the second clock signal Clk₂ on the rising edge of the first clock signal Clk₁. When the value of the latched second clock signal Clk₂ is high, indicating that a rising edge of the first clock signal Clk₁ is occurring before a falling edge of the second clock signal Clk₂ (without taking into consideration a setup time of the flip-flop circuit 410), the flip-flop circuit 410 may send an up signal to the charge pump 430, causing the charge pump 430 to add charge to the capacitor 440.

The flip-flop circuit 420 may be configured to latch a value of the first clock signal Clk₁ on the falling edge of the second clock signal Clk₂. When the value of the latched first clock signal Clk₁ is high, indicating that a falling edge of the second clock signal Clk₂ is occurring before a rising edge of the first clock signal Clk₁ (without taking into consideration a setup time of the flip-flop circuit 420), the flip-flop circuit 420 may send a down signal to the charge pump 430, causing the charge pump 430 to remove charge from the capacitor 440. The voltage on the capacitor 440 may adjust the capacitance C_{V} of the variable capacitor 315.

When the phase of the first and second clock signals Clk₁ and Clk₂ are in resonance, either both the up and down signals may be asserted or neither of the up and down signals may be asserted. In these circumstances, the charge pump 430 may not adjust the charge on the capacitor 440, causing the voltage on the capacitor 440 to remain the same. When the voltage on the capacitor 440 remains the same, the capacitance C_{V} of the variable capacitor 315 may not be adjusted. In some embodiments, additional passive and/or active circuit elements and/or integrated circuits may be part of the phase detector 400. For example, a low pass filter may be added between the capacitor 440 and the variable capacitor 315.

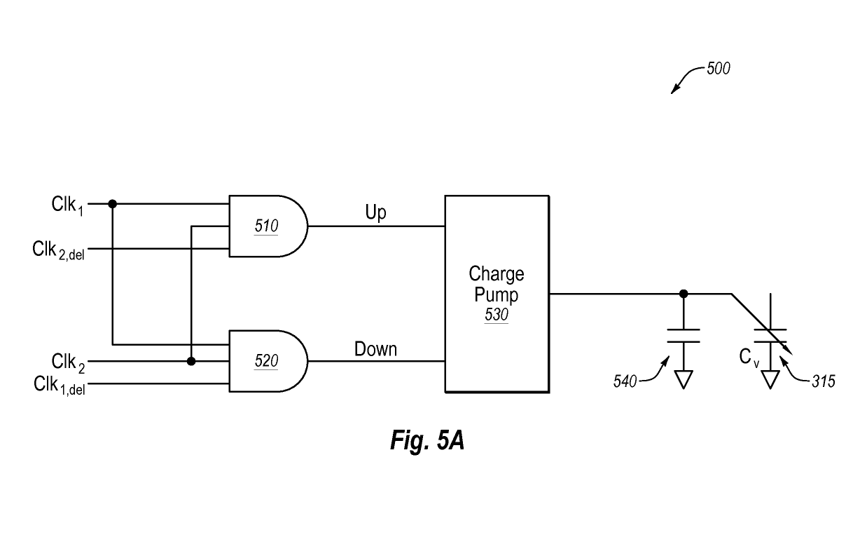

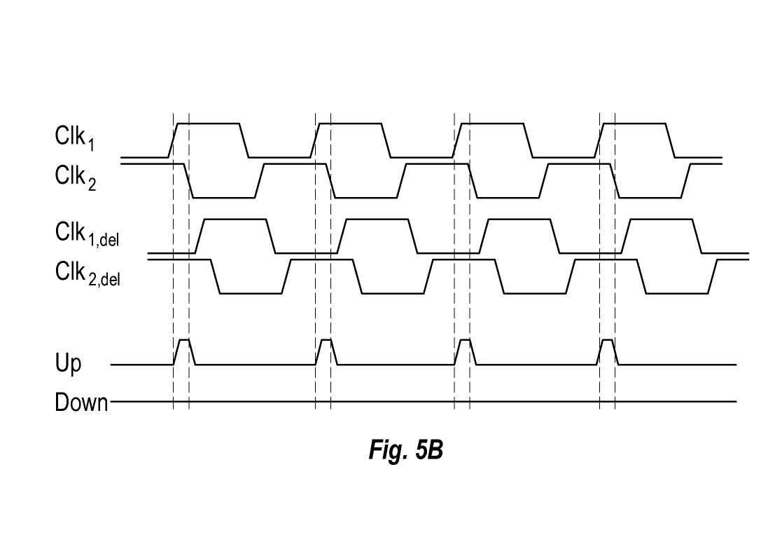

FIG. 5A is an example of another phase detector 500 which may be used in association with the tunable resonant distribution system of FIG. 2 or 3, arranged in accordance with at least some embodiments described herein. The phase detector 500 may correspond to and/or be similar to the 180° phase detector 305 of FIG. 3. The phase detector 500 may include a pair of AND gates 510 and 520 in addition to a charge pump 530 and an associated capacitor 540, all of which may be used to vary a capacitance C_{V} of a variable capacitor 315. The variable capacitor 315 may correspond to the variable capacitor 315 of FIG. 3.

The phase detector 500 may be configured to detect a phase difference between a first clock signal Clk₁ and a second clock signal Clk2 and when the phase difference is not equal to or approximately equal to 180° to send a signal to vary the capacitance C_{V} of the variable capacitor 315. To determine the phase difference between the first and second clock signals Clk₁ and Clk₂, the phase detector 500, and in particular, the AND gates 510 and 520 may be configured to receive first and second clock signals Clk₁ and Clk₂ and first and second delayed clock signals Clk_{1, del} and Clk_{2, del}. The first delayed clock signal Clk_{1, del} may be a delay (i.e. a phase shift) of the first clock signal Clk₁. The second delayed clock signal Clk_{2,del} may be a delay of the second clock signal Clk₂. The first delayed clock signal Clk_{1,del} the second clock signal Clk₂, and the first clock signal Clk₁ may be connected to the AND gate 520. The second delayed clock signal Clk_{2, del}, the second clock signal Clk₂, and first clock signal Clk₁ may be connected to the AND gate 510.

The AND gates 510 and 520 may be configured to produce an up and a down signal respectively for the charge pump 530 based on a phase difference between the first and second clock signals Clk₁ and Clk₂. In particular, when a rising edge of the first clock signal Clk₁ occurs before a falling edge of the second clock signal Clk₂, the AND gate 510 may send the up signal to the charge pump 530. When a rising edge of the second clock signal Clk₂ occurs before a falling edge of the first clock signal Clk₁, the AND gate 520 may send the down signal to the charge pump 530.

The up and down signals may cause the charge pump 530 to respectively send charge to and remove charge from the capacitor 540. By removing charge from or sending charge to the capacitor 540, the voltage on the capacitor 540 is adjusted. Adjusting the voltage on the capacitor 540 may adjust the capacitance C_{V} of the variable capacitor 315.

The first and second delayed clocked signals Clk_{1, del} and Clk_{2, del} may be delayed a sufficient amount to cover a maximum expected phase offset range between the first and second clock signals Clk₁ and Clk₂. The first and second delayed clocked signals Clk_{1, del} and Clk_{2, del} may thus be used as enable signals to help to ensure that the AND gates 510 and 520 send the up and down signals, respectively, when the rising edge of the first clock signal Clk₁ is ahead of the falling edge of the second clock signal Clk₂ and the rising edge of the second clock signal Clk₂ is ahead of the falling edge of the first clock signal Clk₁, respectively. Using the first and second delayed clocked signals Clk_{1, del} and Clk_{2, del} as enable signals may help to reduce erroneous up and/or down signals, which would result in current being sent to or removed from the variable capacitor 315, due to noise or jitter on the first and second clock signals Clk₁ and Clk₂.

FIG. 5B illustrates example signals which may be detected by the phase detector described in FIG. 5A, arranged in accordance with at least some embodiments described herein. In this example, the rising edge of the first clock signal Clk₁ leads the falling edge of the second clock signal Clk₂.

As illustrated, the up signal is asserted for the duration when both the first and second clock signals Clk₁ and Clk₂ are high and then the second delay clock signal Clk_{2, del} is high. With the assertion of the up signal, the charge pump 530 sends charge to the capacitor 540 thereby adjusting the voltage seen by the variable capacitor 315. Based on the voltage seen by the variable capacitor 315, the variable capacitor 315 may adjust its capacitance C_{V}. When the capacitance C_{V} is adjusted, the phase difference between the first and second clock signals Clk₁ and Clk₂ may decrease, leading to less and less time that the up signal is asserted and thus decreasing the voltage change at the variable capacitor 315 and the adjustment of the capacitance C_{V}.

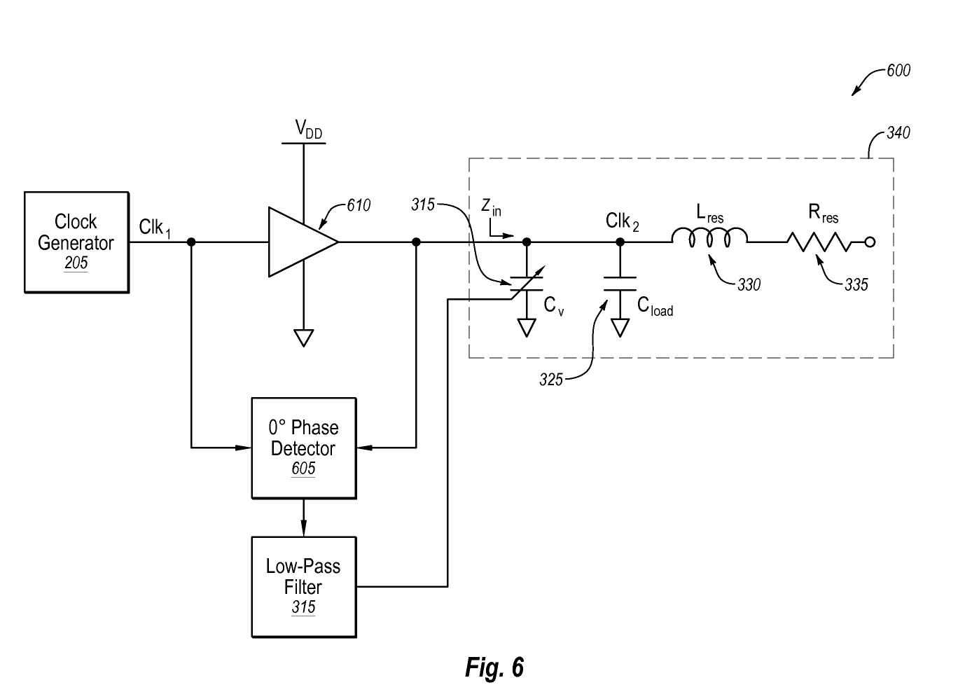

FIG. 6 is an example of another tuned resonant clock distribution system 600, arranged in accordance with at least some embodiments described herein. The tuned resonant clock distribution system 600 may be similar to the tuned resonant clock distribution system 300 of FIG. 3. In the tuned resonant clock distribution system 600, however, an amplifier 610 may distribute the clock signal Clk₁ without inverting the clock signal Clk₁. Because the clock signal Clk₁ is not inverted, the resonant clock distribution system 600 includes a 0° phase detector 605 in place of the 180° phase detector 305 of FIG. 3. The 0° phase detector 605 may detect any phase difference between the clock signal Clk₁ and the resonant clock signal Clk₂ and, when a phase difference occurs, the 0° phase detector 605 may send a signal to adjust the capacitance C_{V} of the variable capacitor 315 to bring the clock signal Clk₁ and the resonant clock signal Clk₂ back into phase.

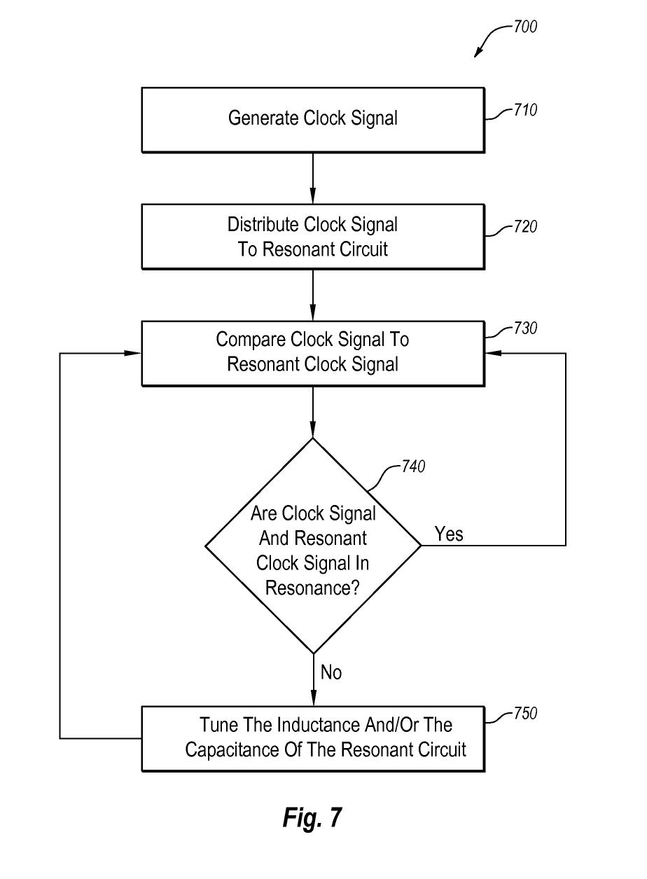

FIG. 7 is a flow chart illustrating a method 700 of tuning a clock distribution system, arranged in accordance with at least some embodiments described herein. The method 700 may be implemented, in some embodiments, by a tuned resonant clock distribution system, such as the tuned resonant clock distribution system 200, 300, or 600 of FIG. 2, 3, or 6 respectively. Although illustrated as discrete blocks, various blocks may be divided into additional blocks, combined into fewer blocks, or eliminated, depending on the desired implementation. The method may begin at block 710, where a clock signal Clk₁ is generated by a clock generator.

In block 720, the clock signal Clk₁ is distributed by a driving circuit to a resonant circuit including a capacitive circuit and an inductive circuit. In block 730, a phase of the clock signal Clk₁ is compared to a phase of a resonant clock signal Clk₂.

In block 740, it is determined if the clock signal Clk₁ and resonant clock signal Clk₂ are in phase, or 180° out of phase. If the clock signal Clk₁ and resonant clock signal Clk₂ are determined to be sufficiently in phase, or sufficiently 180° out of phase, the method 700 returns to block 730 where the resonant circuit continues to resonate while the phases of the clock signal Clk₁ and the resonant clock signal Clk₂ are continuously or periodically compared. Conversely, if the clock signal Clk₁ and the resonant clock signal Clk₂ are not determined to be sufficiently in phase, the method 700 proceeds to block 750.

In block 750, the capacitive circuit and/or the inductive circuit is adjusted in order to tune the inductance and/or capacitance of the resonant circuit. Once the adjustment has been made, the method 700 returns to the block 730 where the phases of the clock signal Clk₁ and the resonant clock signal Clk₂ are continuously or periodically compared.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

Although several embodiments described herein describe tuning a clock network by adjusting or varying a capacitance of the clock network, an impedance of the clock network may also be varied by adding a variable or tunable inductor to the clock network. In this instance, the inductance of the clock network would be increased or decreased in order to ensure a desired phase difference between a clock signal Clk₁ and a resonant clock signal Clk₂. In order to vary the inductance, a plurality of inductance control circuits including banks of inductors may be used to selectively add or remove inductance to the system. Furthermore, digital inductors or other circuit elements with inductance may also be used.

Embodiments described herein control a capacitance and/or an impedance of a clock network to help to ensure a desired phase difference between a clock signal Clk₁ and a resonant clock signal Clk₂ so that an impedance of the clock network is real and the clock network operates at resonance. A system that controls the capacitance and/or inductance of a clock network requires less driving power and a simpler configuration than other methods currently used in the art.

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present inventions have been described in detail, it should be understood that the various changes, substitutions, and alterations could be made hereto without departing from the spirit and scope of the invention.

1. A tunable clock distribution system comprising:
a clock network comprising an inductive circuit and a capacitive circuit, at least one of the capacitive circuit or the inductive circuit being tunable;
a driving circuit configured to receive a clock signal and to distribute a resonant clock signal based on the clock signal to the clock network; and
a phase determiner configured to receive the clock signal and the resonant clock signal and to determine whether the clock signal and the resonant clock signal have a predetermined phase difference, and when the clock signal and the resonant clock signal do not have the predetermined phase difference, the phase determiner is configured to tune at least one of the capacitive circuit or the inductive circuit.

2. The tunable clock distribution system of claim 1, wherein the capacitive circuit comprises a variable capacitor while the inductance of the inductance circuit is fixed.

3. The tunable clock distribution system of claim 1, wherein the inductive circuit further comprises a variable inductor while the capacitance of the capacitive circuit is fixed.

4. The tunable clock distribution system of claim 1, wherein the at least one of the capacitive circuit or the inductive circuit is tuned using digital tuning.

5. The tunable clock distribution system of claim 4, wherein the phase detector comprises a plurality of flip-flops and a charge pump.

6. The tunable clock distribution system of claim 4, wherein the phase detector comprises a plurality of AND gates, a first delay clock signal, and a second delay clock signal.

7. The tunable clock distribution system of claim 1, wherein the predetermined phase difference is one of 0° or 180°.

8. The tunable clock distribution system of claim 1, wherein the capacitive circuit comprises a plurality of capacitors connected via a series of switches, a varactor, or a transistor.

9. An integrated circuit comprising:
a clock generator configured to generate a clock signal;
a driving circuit configured to distribute the clock signal;
a clock network comprising an inductive circuit and a capacitive circuit connected to the driving circuit, at least one of the capacitive circuit or the inductive circuit being tunable; and
a phase determiner configured to receive the clock signal from the clock generator and a resonant clock signal from the clock network, the phase determiner configured to determine whether the clock signal and the resonant clock signal have a predetermined phase difference, and when the clock signal and the resonant clock signal do not have the predetermined phase difference, the phase determiner is configured to tune at least one of the capacitive circuit or the inductive circuit.

10. The integrated circuit of claim 9, wherein the capacitive circuit comprises a variable capacitor while the inductance of the inductive circuit is fixed.

11. The integrated circuit of claim 9, wherein the inductive circuit further comprises a variable inductor while the capacitance of the capacitive circuit is fixed.

12. The integrated circuit of claim 9, wherein the determiner comprises a phase detector and a low-pass filter.

13. The integrated circuit of claim 12, wherein the phase detector comprises a plurality of flip-flops and a charge pump.

14. The integrated circuit of claim 12, wherein the phase detector comprises a plurality of AND gates, a first delay clock signal, and a second delay clock signal.

15. The integrated circuit of claim 12, wherein the predetermined phase difference is one of 0° or 180°.

16. The integrated circuit of claim 9, wherein the at least one of the capacitive circuit or the inductive circuit is tuned using digital tuning.

17. A method for tuning a resonant clock distribution network, the method comprising:
receiving a clock signal;
distributing the clock signal to a clock network that includes an inductive circuit and a capacitive circuit, at least one of the capacitive circuit or the inductive circuit being tunable;
comparing a phase of the clock signal to a phase of a resonant clock signal of the clock network;
determining whether a predetermined phase shift exists between the clock signal and the resonant clock signal; and
tuning at least one of the capacitive circuit or the inductive circuit when it is determined that the predetermined phase shift does not exist between the clock signal and the resonant clock signal.

18. The method of claim 17, wherein the capacitive circuit comprises a variable capacitor while the inductance of the inductive control circuit is fixed, wherein tuning the at least one of the capacitive circuit and the inductive circuit comprises adjusting the capacitance of the variable capacitor.

19. The method of claim 18, wherein adjusting the capacitance of the variable capacitor comprises adjusting a voltage at the variable capacitor.

20. The method of claim 17, wherein the inductive circuit comprises a variable inductor while the capacitance of the capacitive control circuit is fixed, wherein tuning the at least one of the capacitive circuit and the inductive circuit comprises adjusting the inductance of the variable inductor.
